(19) United States
(12) Patent Application Publication
(10) Pub. No.: US 2013/0306929 A1
(43) Pub. Date: Nov. 21, 2013

(54) Multilayer-Stacked Phase Change Memory Cell

(71) Applicants: Jaeho Lee, Stanford, CA (US); John P. Reifenberg, Walnut Creek, CA (US); Mehdi Asheghi, Emeryville, CA (US); Kenneth E. Goodson, Portola Valley, CA (US); H.S. Philip Wong, Stanford, CA (US); SangBum Kim, Stamford, CT (US)

(72) Inventors: Jaeho Lee, Stanford, CA (US); John P. Reifenberg, Walnut Creek, CA (US); Mehdi Asheghi, Emeryville, CA (US); Kenneth E. Goodson, Portola Valley, CA (US); H.S. Philip Wong, Stanford, CA (US); SangBum Kim, Stamford, CT (US)

(21) Appl. No.: 13/472,931

(22) Filed: May 16, 2012

(51) Int. Cl. H01L 45/00

(52) U.S. Cl. 257/4; 257/E45.001

(57) ABSTRACT

A multilayer-stacked phase change memory (PCM) device is provided that includes a substrate that is electrically insulative and thermally conductive, a number (n) of PCM layers deposited on the substrate, where each PCM layer is thicker than a previous PCM layer, a number (n−1) layers of passivation layer deposited between the PCM layers, where the (n) PCM layers, and the (n−1) passivation layers form a stacked multi-layer PCM on the substrate, a first electrode deposited on a first side of the multi-layer PCM stack, and a second electrode deposited on a second side of the multi-layer PCM stack, where the first side is opposite the second side, where charge transport is decoupled by stacking the PCM layers with the pasivation layers.

### STATEMENT OF GOVERNMENT SPONSORED SUPPORT

This invention was made with Government support under contract 0853350 awarded by National Science Foundation. The Government has certain rights in this invention.

### FIELD OF THE INVENTION

The invention relates generally to memory storage devices. More particularly the invention relates to Multi-Bit Phase Change Memory storage devices.

### BACKGROUND OF THE INVENTION

Forming and programming a multi-bit phase change memory devices are challenging and ongoing endeavors. Some attempts possess two accessible electrode structures, and achieve multiple resistance states by varying the amount of current or voltage applied. However, these devices electrodes conduct energy vertically rather than laterally by using metal between the GST layers, which limits performance, where the device performs as a group of electrical resistors in series making the device voltage-driven, which requires more voltage to generate the heating power necessary for switching. The fabrication steps required to create this structure are complex and numerous.

In another example, switching was performed by laser pulses, while the methods for reading the information included electrical resistance, capacitance, dielectric constant, index of light refraction, surface reflectance, light absorption, and light transmission and particle scattering properties. This device is overly complex and highly expensive

Another attempt included creating multi-level operation in an arbitrary PCM device. This method, basically a guess-and-check algorithm, verifies whether a cell has been properly written. If not, it iteratively corrects the bad bit.

A further instance included a pillar phase change memory cell. The goal of this design is to use the dissimilar switching properties of the three materials to achieve multi-bit performance. However, this cell is not truly multi-bit. There are no well-defined resistance levels other than the three phases of the material. Further, the lack of insulating material between the three materials raises the MTBF due to mixing of the three layers over time.

The above examples achieve multi-bit operation through the use of a Word-Line/Bit-Line (WLBL) system. Such a system uses multiple PCM devices stacked on various electrode lines. A voltage drop is set up across one bit line and one word line. This selects the set of PCM cells through which current flows. The bit and word lines run perpendicular to each other, and are offset by the thickness of the individual PCM device. While these are multi-bit structure, they require individually setting each cell to achieve multiple resistance levels.

Although not a WLBL structure, another multi-bit cell uses multiple electrodes to access a plurality of PCM devices. The device has three electrodes, two heaters, and two memory material bits, where this device only allows access to two bits. Further, it takes up space and includes some lateral electrical conduction through the device.

Other devices use multiple electrodes to access multiple PCM devices. While this does produce an effective multi-bit solution, such structures are exceedingly complex and require a great deal of programming skill to implement.

A further attempt utilizes multiple layers of varying resistance phase change material with a single electrode access in order to create multiple resistance levels by varying heating current. Each layer has a different electrical resistance, so for a given input current, the highest electrical resistance layer RESETs first.

Another example includes using differing thermal properties to control the degree of phase change in a cell, where the memory material is surrounded by two different passivation materials, one of which is more thermally conductive than the other. As a result, the memory material on the more conductive side will cool down faster, and be less likely to change phase. This allows the user to control the degree of phase change, and theoretically create a multi-bit cell. However, this does not result in multiple resistance levels. Rather, it increases the amount of current required to change an individual bit, thereby increasing the phase resolution at the cost of more current.

What is needed is a PCM device that is capable of providing a multi-bit structure simply by applying varying levels of current.

### SUMMARY OF THE INVENTION

To address the needs in the art, a multilayer-stacked phase change memory (PCM) device is provided that includes a substrate that is electrically insulative and thermally conductive, a number (n) of PCM layers deposited on the substrate, where each PCM layer is thicker than a previous PCM layer, a number (n−1) layers of passivation layer deposited between the PCM layers, where the (n) PCM layers, and the (n−1) passivation layers form a stacked multi-layer PCM on the substrate, a first electrode deposited on a first side of the multi-layer PCM stack, and a second electrode deposited on a second side of the multi-layer PCM stack, where the first side is opposite the second side, where charge transport is decoupled by stacking the PCM layers with the pasivation layers.

In one aspect of the invention, the substrate can be silicon, silicon carbide GaAs, or GaN.

According to another aspect of the invention, (n) is in a range of 3 to 7.

In a further aspect of the invention, the PCM layers can be chalcogenide semiconductors that provide threshold switching and phase changes. In one aspect the PCM layers include Ge₂Sb₂Te₅ (GST) material.

In another aspect of the invention, the passivation layer includes an electrically insulating material. Here, the electrically insulating material can be SiO₂, Si₃N₄, or sapphire.

In yet another aspect of the invention, the passivation layer has a thickness up to 100 nm.

According to one aspect of the invention, a first the PCM layer has a thickness in a range of 10 nm to 500 nm.

In another aspect of the invention, a second the PCM layer has a thickness that is greater than the first layer by an amount up to 500 nm.

In yet another aspect of the invention, a third the PCM layer has a thickness that is greater than the second layer by an amount up to 500 nm.

According to one aspect of the invention, the electrodes are can be TiN, W, Pt, AlCu, C, Ta, or Ti.

In another aspect of the invention, a distance between the first electrode and the second electrode is up to 100 μm across the stacked multi-layer PCM.

### BRIEF DESCRIPTION OF THE DRAWINGS

FIGS. 1a-1b show perspective schematic drawings of multilayer stacked PCM structures having a substrate that is uncoated and coated with a passive layer, according to embodiments of the current invention.

FIGS. 2a-2b show a perspective views of exemplary multilayer stacked PCM structures without and with an optional heater layer, according to one embodiment of the invention.

FIGS. 3a-3e show simulation images of successive layers in the exemplary multilayer stacked PCM structure of FIG. 2a being RESET with increased voltage, according to one embodiment of the invention.

FIG. 4 shows a plot of the resistance versus programming current having four distinct resistance levels for the structure of FIG. 2, according to one embodiment of the invention.

FIGS. 5a-5b show the SET process for the structure of FIG. 2, according to one embodiment of the invention.

FIG. 6 shows a plot of the resistance versus programming current having a reduction to no levels for the structure of FIG. 2, according to one embodiment of the invention.

### DETAILED DESCRIPTION

Phase change memory (PCM) is a solid-state data storage technique capable of greater data storage density than existing technologies. A lateral PCM device is provided to achieve multilevel programming with distinct levels of resistance. According to one embodiment, the multilayer-stacked PCM (MSPCM) structure decouples the charge transport by stacking the phase change materials with passivation layers. Simulation models are provided to demonstrate the phase change memories can significantly improve their storage density through multilevel programming. Novel phase change memories can benefit from the multilevel and cell optimization strategies presented here and make the PCM a viable technology in the future.

One embodiment a PCM device includes two electrodes, a optional heater layer, a phase-change material (a chalcogenide such as Ge₂Sb₂Te₅ (GST)) sandwiched in between, and some form of passivation (such as SiO₂) surrounding the phase change material. In the case of GST, there are three such phases: amorphous, face-centered cubic (FCC), and hexagonal close-packed (HCP). The electrical resistivities of the various phases differ significantly, allowing data storage in the form of the electrical resistance of the PCM cell. By applying a current pulse across the two electrodes, one induces self-heating in the GST and heater layers due to their electrical resistance. This heating pulse raises the temperature of the GST by several hundred Kelvin over a period of nanoseconds to microseconds. By controlling the heating profile over time, the device selectively switches between the various phases of GST. Switching from the amorphous to the crystalline phase is referred to as a SET operation, while the opposite operation is referred to as RESET.

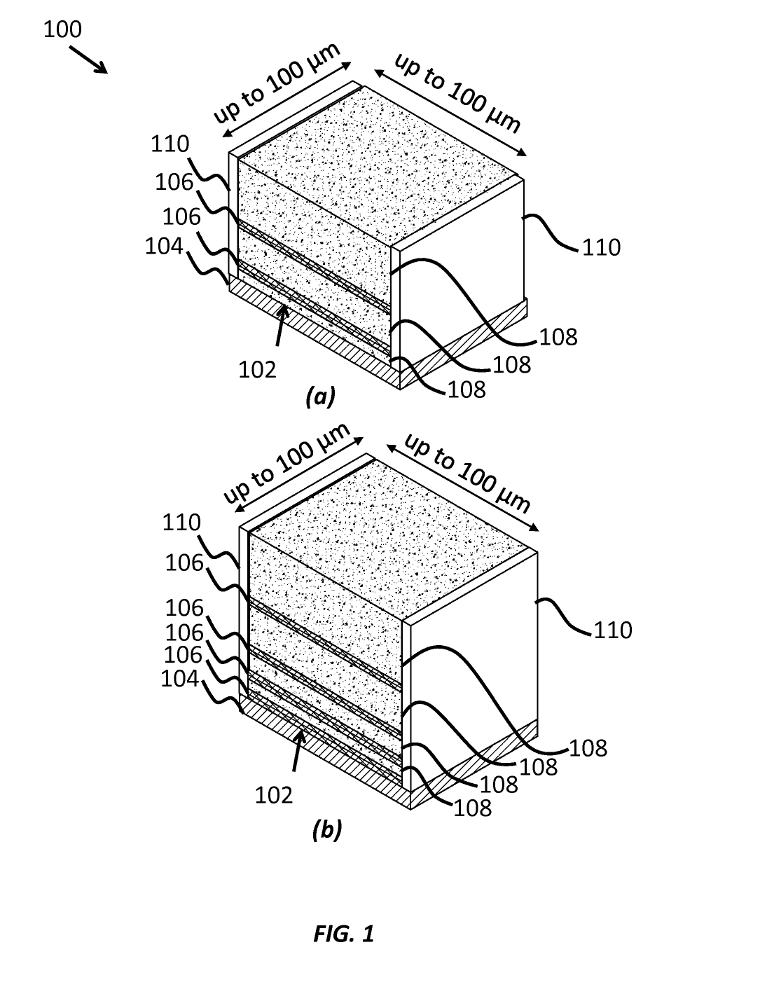

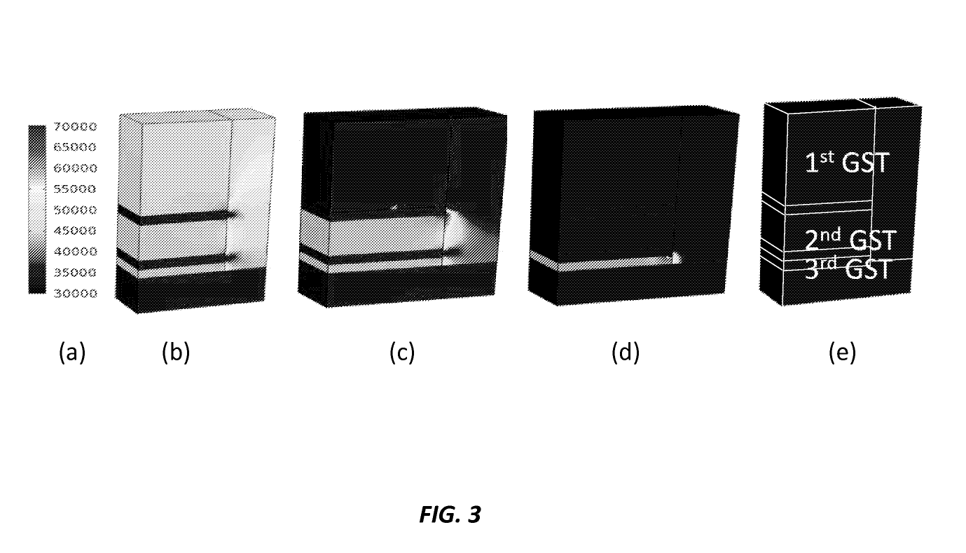

According to the embodiments shown in FIGS. 1a-1b, a lateral PCM design 100 is disposed to achieve multilevel programming with distinct levels of resistance. The multilayer-stacked PCM (MSPCM) structure 102 decouples the charge transport by stacking the phase change materials with passivation layers. Simulation models demonstrate that the phase change memories can significantly improve their storage density through multilevel programming (see FIGS. 3-6). Novel phase change memories benefit from the multilevel and cell optimization strategies presented here.

In FIGS. 1a-1b, the memory structure 102 sits on a low thermal conductivity material substrate 104 to prevent heat loss to the environment. This embodiment includes a substrate material 104 that is electrically insulating and thermally conductive. Examples of this material may be silicon, silicon carbide, GaAs, GaN or other commercially available substrates. A thin electrically insulating passivation layer 106 (>10 nanometers in thickness) can be applied to coat the surface of the substrate 104 to ensure electrical insulation (see FIG. 1b). A thin passivation layer is desired as long as it's electrically insulating. Here, the electrically insulating material can be SiO₂, Si3N₄, or sapphire, where an appropriate thickness range would be 20˜100 nm.

The passivation material 106 may be silicon dioxide, silicon nitride, sapphire, or any other electrically and thermally-resistive material. At least two layers of phase change material 108 (typically GST, though other materials may be used) are deposited on top of the substrate surface 104, or the pasivation layer 106 covering the substrate surface 104, each with varying thickness, where thin passivation layers separate each phase change material layer 108. Two electrodes 110 are applied to flank the stacked memory structure 102, and providing electrical access to the device 100. According to one aspect of the invention, a first the PCM layer has a thickness in a range of 10 nm to 500 nm, a second the PCM layer has a thickness that is greater than the first layer by an amount up to 500 nm, and a third the PCM layer has a thickness that is greater than the second layer by an amount up to 500 nm.

These electrodes 110 may include TiN, W, Pt, AlCu, C, Ta, Ti, amorphous carbon, or any other electrically-conductive and thermally-resistive material, where a distance between the first electrode and the second electrode is up to 100 μm across the stacked multi-layer PCM.

The passivation layers 106 electrically and thermally confine each PCM layer 108. Since this makes it more difficult for each PCM layer 108 to lose heat, the layers heat up faster and switch with less current.

Each PCM layer 108 has a different vertical thickness, but the same length. As a result, the thicker layers have lower electrical resistance than the thinner ones. For a given current applied between the two electrodes 110, the heating power is greatest for the PCM thinnest layer 108. If the entire cell starts in the SET state, this causes the thinnest layer to RESET first, while the others remain undisturbed. Applying a greater voltage causes the next layer to RESET, and one can continue this increase until all the bits are RESET (see FIGS. 3a-3e). To perform a SET operation, one heats the device 100 with a smaller current pulse over a longer time period. Therefore, if the device 100 contains n layers of memory material, there are (n+1) potential memory levels, where there may be (n−1) passivation layers when no layer is applied to the substrate surface or (n) passivation layers when one is applied.

The three PCM layer design provides four resistance levels, which correspond to 2-bit-per-cell. As an example, if there are 7 PCM layers, 8 resistance levels are achieved, which correspond to 3-bit-per-cell. In more layers are possible, for example 15 PCM layers provides 4-bit-per-cell, where the control of programming each PCM layer becomes more complex.

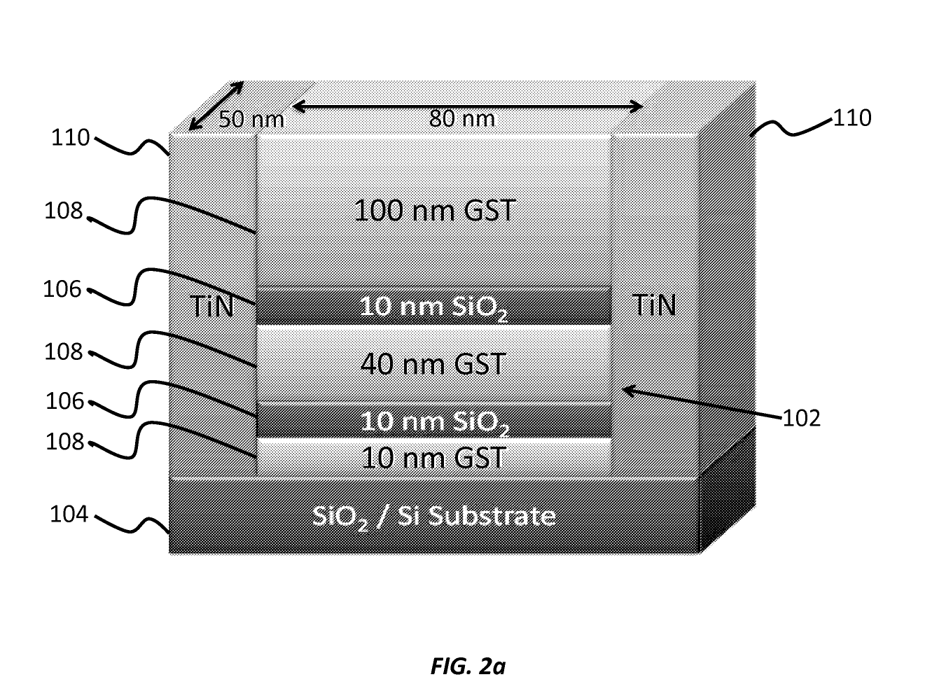

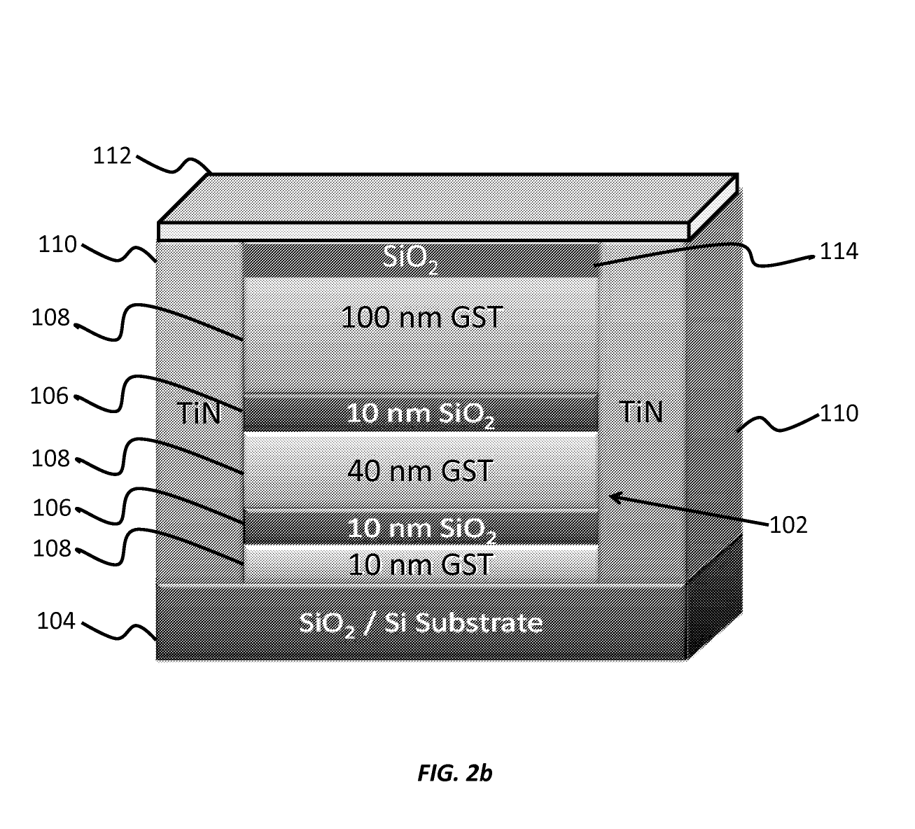

FIGS. 2a-2b show a perspective views of exemplary multilayer stacked PCM structures 100, according to one embodiment of the invention. Here, the dimensions of each PCM layer 108 (shown as GST material) is varied to improve the programming conditions, while the passivation layer 106 is shown as remaining the same thickness. By storing multiple data bits per cell, multi-bit technology provides a higher bit density for phase-change memory. The current invention achieves multiple levels of resistance by stacking the phase change materials separated by passivation layers. Applying a large electrical pulse at the electrodes 110 (shown as TiN material) induces the phase change starting from the top GST layer 108 to the bottom GST layer 108 depending on the magnitude of programming current, where the multilayer-stacked PCM 102 provides a larger resistance margin and thus greater tolerance to the resistance drift. The dimensional length of the electrode 110 along the side of the multilayer-stacked PCM 102, where this dimension can be up to 100 μm, where longer distance require larger voltage and larger electrical stresses that can damage the PCM layers 108. FIG. 2b shows the multilayer stacked PCM structure 100 having an optional heater layer 112 deposited on top of the multilayer-stacked PCM 102, where the optional heater layer 112 connects directly to the electrodes 110 and has an insulating layer 114 (for example SiO₂) between the top PCM layer 108 and the optional heater layer 114.

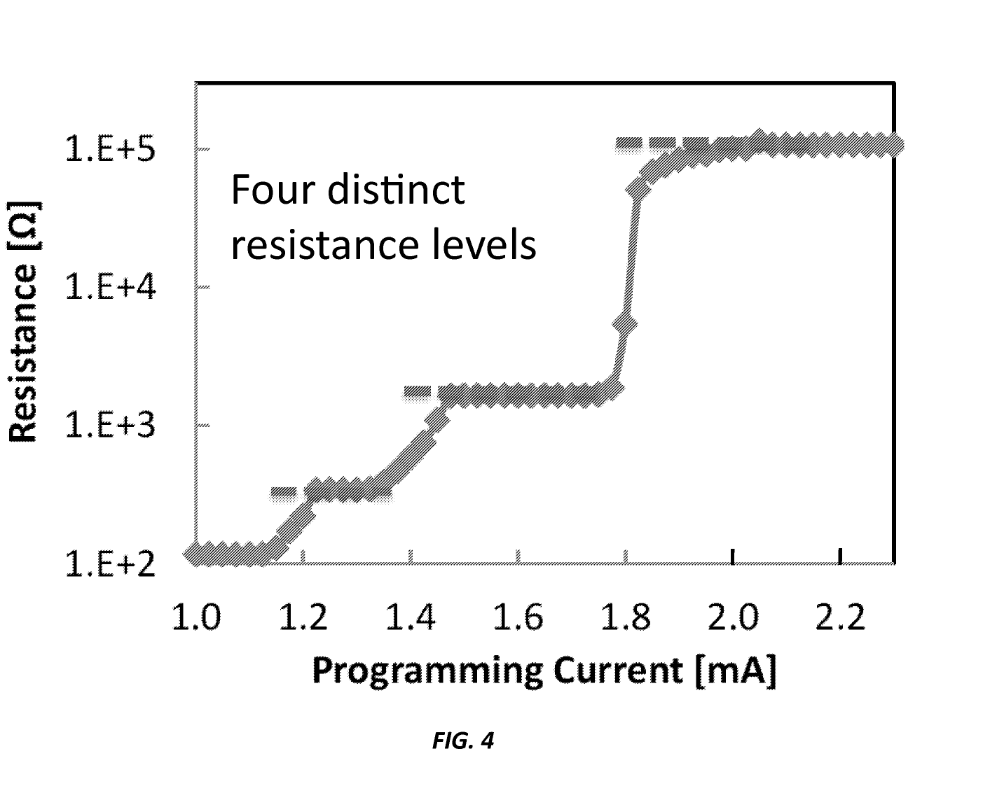

According to one embodiment, the MSPCM cell achieves multiple resistance states by varying the amount of current or voltage applied. The electrodes conduct energy laterally rather than vertically and the MSPCM design implements parallel conduction paths. This results in reduced programming power and increased gap between resistance levels. FIGS. 3a-3e show simulation images of successive layers in the exemplary multilayer stacked PCM structure of FIG. 2 being RESET with increased voltage, according to one embodiment of the invention. The temperature rise is largest in the top layer, which becomes amorphous (reset) first. Parallel electrical connection of PC cells creates large gaps between resistance levels. FIG. 4 shows a plot of the resistance versus programming current having four distinct resistance levels for the structure of FIG. 2, according to one embodiment of the invention.

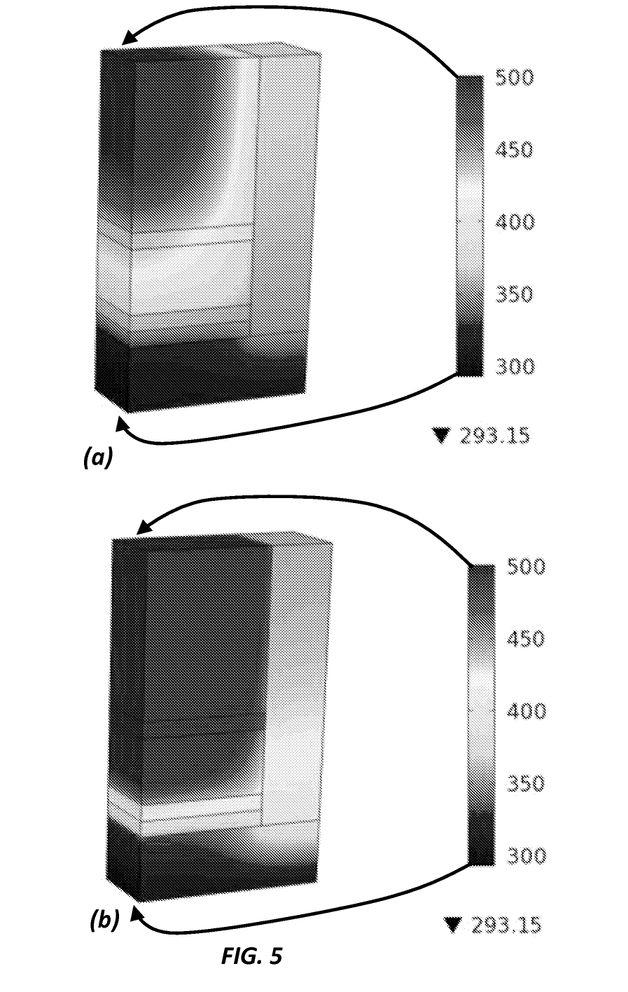

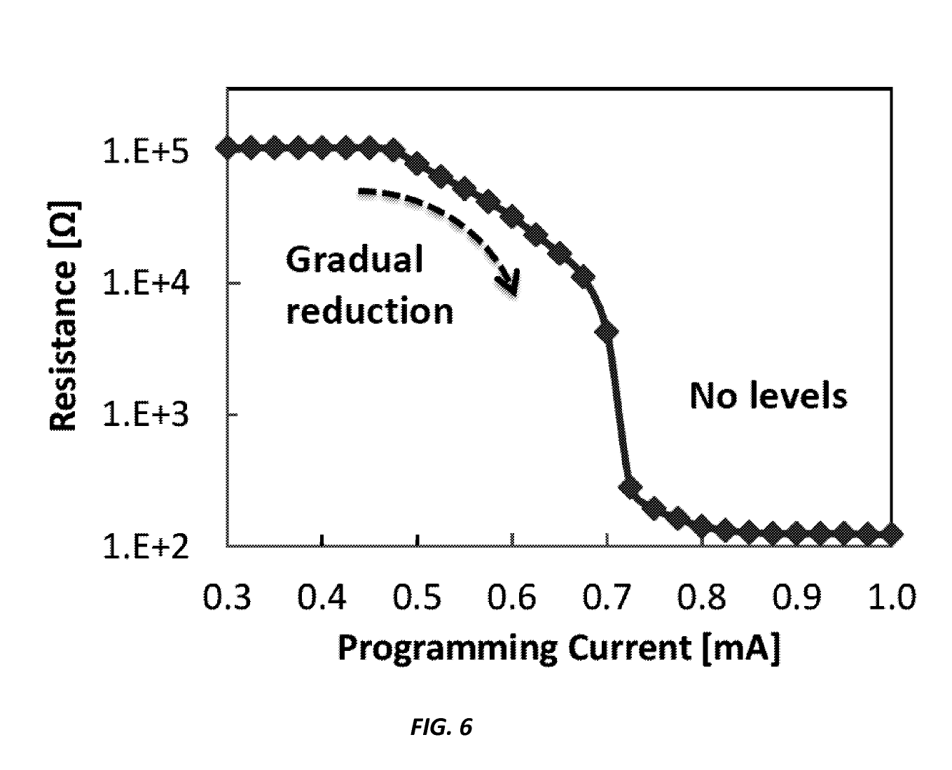

FIGS. 5a-5b show the SET process for the structure of FIG. 2, according to one embodiment of the invention. Electrical threshold switching allows enough temperature rise (>500 K) for crystallization. The gradual reduction in resistance is due to crystallization of the top (largest) GST layer. FIG. 6 shows a plot of the resistance versus programming current having a reduction to no levels for the structure of FIG. 2, according to one embodiment of the invention. These simulations on the lateral, unconfined devices 100 show unexpected results in a sloped current-resistance relation, with little differentiation between levels.

Phase-change memory blends the attributes of competing memory technologies including NORtype flash memory, NAND-type flash memory, EEPROM memory, and DRAM and is a leading candidate for the next generation of nonvolatile memory (NVM), expanding the use of NVM in computing and storage systems. As traditional electron storage-based memories such as NOR and NAND flash begin to encounter scaling difficulties, PCM is considered to be the best candidate to continue the scaling of NVM.

Although binary data storage is currently the norm, greater storage densities are provided by the current invention. Instead of storing information in a 0-1 format, the current invention allows the use of 0-1-2-3-etc.

The current invention reduces the total number of individual cells required to store a given amount of information. The multi-bit PCM cell includes more than two stable states, and the cell has multiple, distinguishable resistance levels, rather than a linear relation between resistance and switching current.

The present invention has now been described in accordance with several exemplary embodiments, which are intended to be illustrative in all aspects, rather than restrictive. Thus, the present invention is capable of many variations in detailed implementation, which may be derived from the description contained herein by a person of ordinary skill in the art. All such variations are considered to be within the scope and spirit of the present invention as defined by the following claims and their legal equivalents.

What is claimed:

1. A multilayer-stacked phase change memory (PCM) device, comprising:
a. a substrate, wherein said substrate is electrically insulative and thermally conductive;
b. a number (n) of PCM layers deposited on said substrate, wherein each said PCM layer is thicker than a previous said PCM layer;
c. a number (n−1) layers of passivation layer deposited between said PCM layers, wherein said (n) PCM layers, and said (n−1) passivation layers form a stacked multi-layer PCM on said substrate;
d. a first electrode deposited on a first side of said multi-layer PCM stack; and
e. a second electrode deposited on a second side of said multi-layer PCM stack, wherein said first side is opposite said second side, wherein charge transport is decoupled by stacking said PCM layers with said pasivation layers.

2. The multilayer-stacked phase change memory (PCM) device of claim 1, wherein said substrate is selected from the group consisting of silicon, silicon carbide GaAs, and GaN.

3. The multilayer-stacked phase change memory (PCM) device of claim 1, wherein (n) is in a range of 3 to 7.

4. The multilayer-stacked phase change memory (PCM) device of claim 1, wherein said PCM layers comprise chalcogenide semiconductors that provide threshold switching and phase changes.

5. The multilayer-stacked phase change memory (PCM) device of claim 4, wherein said PCM layers comprise Ge2Sb2Te5 (GST) material.

6. The multilayer-stacked phase change memory (PCM) device of claim 1, wherein said passivation layer comprises an electrically insulating material.

7. The multilayer-stacked phase change memory (PCM) device of claim 7, wherein said electrically insulating material is selected from the group consisting of SiO2, Si₃N₄, and sapphire

8. The multilayer-stacked phase change memory (PCM) device of claim 1, wherein said passivation layer has a thickness up to 100 nm.

9. The multilayer-stacked phase change memory (PCM) device of claim 1, wherein a first said PCM layer comprises a thickness in a range of 10 nm to 500 nm.

10. The multilayer-stacked phase change memory (PCM) device of claim 1, wherein a second said PCM layer comprises a thickness that is greater than said first layer by an amount up to 500 nm.

11. The multilayer-stacked phase change memory (PCM) device of claim 1, wherein a third said PCM layer comprises a thickness that is greater than said second layer by an amount up to 500 nm.

12. The multilayer-stacked phase change memory (PCM) device of claim 1, wherein said electrodes are selected from the group consisting of TiN, W, Pt, AlCu, C, Ta, and Ti.

13. The multilayer-stacked phase change memory (PCM) device of claim 1, wherein a distance between said first electrode and said second electrode is up to 100 μm across said stacked multi-layer PCM.

14. The multilayer-stacked phase change memory (PCM) device of claim 1, wherein said stacked multi-layer PCM comprises a width across said first electrode and across said second electrode up to 10 nm.

15. The multilayer-stacked phase change memory (PCM) device of claim 1, wherein said stacked multi-layer PCM comprises (n) distinct resistance levels.

16. The multilayer-stacked phase change memory (PCM) device of claim 1 further comprises a heater layer, wherein said heater layer is deposited on top of the multilayer stack.
